(19) United States
(12) Patent Application Publication
(10) Pub. No.: US 2015/0179842 A1
(43) Pub. Date: Jun. 25, 2015

(54) RECTIFIER AND TERAHERTZ DETECTOR USING THE SAME

(71) Applicant: Electronics and Telecommunications Research Institute, Daejeon (KR)

(72) Inventors: Jeong Woo PARK, Daejeon (KR); Sang Pil HAN, Daejeon (KR); Dae Yong KIM, Daejeon (KR); Hyun Sung KO, Seoul (KR); Nam Je KIM, Daejeon (KR); Ki Won MOON, Pohang-si (KR); Il Min LEE, Seoul (KR); Eui Su LEE, Busan (KR); Kyung Hyun PARK, Daejeon (KR)

(73) Assignee: Electronics and Telecommunications Research Institute, Daejeon (KR)

(21) Appl. No.: 14/307,856

(22) Filed: Jun. 18, 2014

(30) Foreign Application Priority Data
Dec. 19, 2013 (KR) 10-2013-0159252

(51) Int. Cl. H01L 31/0352; H01L 31/18

(52) U.S. Cl. CPC H01L 31/03529; H01L 31/18

(57) ABSTRACT

Disclosed is a rectifier capable of performing a high speed rectifying operation, and includes: a first semiconductor layer; a second semiconductor layer; and a third semiconductor layer, in which the first semiconductor layer and the third semiconductor layer are formed of semiconductor layers having the same type, and the second semiconductor layer is formed between the first semiconductor layer and the third semiconductor layer, is formed of a semiconductor layer having a different type from that of the first semiconductor layer and the third semiconductor layer, and is formed in graded doped state.

### CROSS-REFERENCE TO RELATED APPLICATION

This application is based on and claims priority from Korean Patent Application No. 10-2013-0159252, filed on Dec. 19, 2013, with the Korean Intellectual Property Office, the disclosure of which is incorporated herein in its entirety by reference.

### BACKGROUND

1. Field

The present invention relates to a rectifier and a terahertz detector using the same, and more particularly, to a rectifier capable of implementing a high speed rectifying characteristic by forming a semiconductor layer having a different type from that of a plurality of semiconductor layers between the plurality of semiconductor layers, which is formed in the same type, in a graded doped state, and a terahertz detector using the same.

2. Discussion of Related Art

Terahertz is electromagnetic wave having a light transmitting property and is a term of a combination of tera denoting 10¹² and hertz that is a unit of the number of vibration. Terahertz is written by Thz and is also referred to as terahertz radiation or T-ray. The terahertz has both a light transmitting property of radio waves and linearity of light waves, so that significance thereof is gradually increased in a basic science field, such as a device, a spectrum, and an image technique, and an applied science field, such as medical engineering, security, environment/space, and information and communication.

A method of measuring mechanical displacement has been initially used as a method of detecting a terahertz wave. The reason is that since the terahertz wave is one type of heat, a material receiving the terahertz wave may be mechanically expanded, and thus the terahertz wave may be measured by measuring a change in the caused mechanical displacement. However, there is a problem in that the method of measuring the mechanical displacement is weak to a vibration, and has greatly large noises.

Accordingly, in order to solve the problem, a new method using a Schottky diode has appeared. The method using the Schottky diode means a method of detecting a terahertz wave by using a high speed rectification operation of the Schottky diode. The method using the Schottky diode may have high responsivity and exhibit a low noise characteristic, thereby widely used as a promising technology of detecting a terahertz wave. However, the method using the Schottky has a problem in that it is difficult to simultaneously improve responsivity performance and rectification operation performance. Particularly, in the Schottky diode, when a doping concentration of a semiconductor is increased in a metal and semiconductor junction, a rectifying characteristic deteriorates, and when a doping concentration of the semiconductor is decreased, responsivity deteriorates, so that there is a problem in that the rectifying characteristic and responsivity have a trade-off relationship. Further, a variable in designing is limited, so that it is difficult to implement various rectifying characteristics.

Accordingly, a new rectifier capable of solving the Schottky diode in the related art has been demanded. Particularly, a new rectification element, which is capable of implementing a high speed rectifying characteristic, does not have a strong trade-off relationship between the rectifying characteristic and responsivity, and has various design variables, has been demanded.

The present invention is invented based on the aforementioned technical background, and is invented in order to provide additional technical elements which meet the aforementioned technical demands and those skilled in the art may not easily invent.

In the meantime, the present invention has been deducted in a process of solving the problem in the terahertz wave detection field, but is not limited to application of this field. That is, the present invention may be utilized in various fields demanding a “high speed rectification operation” as well as the terahertz detection field.

### SUMMARY

The present invention has been made in an effort to provide a rectifier having a new structure, which is capable of performing a high speed rectification operation, thereby being utilized in various technical fields including a terahertz detection field.

In the meantime, technical objects to be achieved by the present invention are not limited to the aforementioned objects, and may include various technical objects within the scope apparent to those skilled in the art from the contents to be described below.

An embodiment of the present invention provides a rectifier, including: a first semiconductor layer; a second semiconductor layer; and a third semiconductor layer, in which the first semiconductor layer and the third semiconductor layer are formed of semiconductor layers having the same type, and the second semiconductor layer is formed between the first semiconductor layer and the third semiconductor layer, is formed of a semiconductor layer having a different type from that of the first semiconductor layer and the third semiconductor layer, and is formed in graded doped state.

Further, in the rectifier according to the exemplary embodiment of the present invention, the second semiconductor layer may be formed in the spatially graded doped state between the first semiconductor layer and the third semiconductor layer.

Further, in the rectifier according to the exemplary embodiment of the present invention, the first semiconductor layer and the third semiconductor layer may be formed of p-type semiconductor layers, and the second semiconductor layer may be formed of a graded doped n-type semiconductor layer.

Further, in the rectifier according to the exemplary embodiment of the present invention, the first semiconductor layer and the third semiconductor layer may be formed of n-type semiconductor layers, and the second semiconductor layer is formed of a graded doped p-type semiconductor layer.

Further, the rectifier according to the exemplary embodiment of the present invention may be operated as a terahertz detector based on a high speed rectifying operation.

Further, in the rectifier according to the exemplary embodiment of the present invention, the first semiconductor layer, the second semiconductor layer, or the third semiconductor layer may be formed through an ion implant process or an epitaxial growth process.

Another embodiment of the present invention provides a terahertz detector: a plurality of first type semiconductors formed of semiconductors having the same type; and a second type semiconductor formed between the plurality of first type semiconductors, formed in a different type from that of the plurality of first type semiconductors, and formed in a graded doped state.

Further, in the terahertz detector according to the exemplary embodiment of the present invention, the second type semiconductor may be formed in the graded doped state according to a change in a distance from the first type semiconductor.

Yet another embodiment of the present invention provides a method of manufacturing a rectifier, including: (a) setting a parameter of semiconductor layers having the same type, or a parameter of a semiconductor layer graded doped in a different type from that of the semiconductor layers having the same type; and (b) forming a semiconductor structure in which the graded doped semiconductor layer is joined between the semiconductor layers having the same type.

Further, in the method of manufacturing the rectifier according to the exemplary embodiment of the present invention, step (a) includes setting doping concentrations of the semiconductor layers having the same type, a width of the graded doped semiconductor layer, or a doping concentration of the graded doped semiconductor layer.

According to the exemplary embodiments of the present invention, it is possible to implement a high speed rectifier by forming a semiconductor layer having a different type from that of a plurality of semiconductor layers formed in the same type between the plurality of semiconductor layers formed in the same type in a graded doped state. Accordingly, the present invention may be utilized in various fields, such as a terahertz detecting field, demanding a high speed rectifying characteristic.

Further, according to the exemplary embodiments of the present invention, it is possible to implement a rectifier having a new type having various design variables, compared to the rectifier in the related art, such as the Schottky diode. Particularly, the present invention may implement a rectifier capable of freely adjusting a high speed rectifying characteristic by using various design variables, such as doping concentrations of semiconductor layers (the first semiconductor layer and the third semiconductor layer) having the same type, a width of the semiconductor layer (the second semiconductor layer) having a different type, and a graded doping concentration of the semiconductor layer (the second semiconductor layer) having the different type. (For reference, in the Schottky diode used in the related art, design variables are limited, so that it is difficult to freely design a characteristic, and a trade-off relationship between a rectifying action and a response speed is a problem.).

Further, according to the exemplary embodiments of the present invention, it is possible to implement a rectifier with a simple structure including the first semiconductor layer, the second semiconductor layer, and the third semiconductor layer, thereby implement a micro-miniature rectifier.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A and 1B are diagrams illustrating an example of a rectifier according to an exemplary embodiment of the present invention;

FIG. 2 is a graph illustrating an I-V characteristic of the rectifier according to the exemplary embodiment of the present invention;

FIG. 3 is a conceptual diagram for describing a principle of flow of a current in the rectifier according to the exemplary embodiment of the present invention; and

FIG. 4 is a graph illustrating an example of an internal electric field generated by graded doping according to the exemplary embodiment of the present invention.

### DETAILED DESCRIPTION

Hereinafter, a rectifier, a terahertz detector, and a method of manufacturing a rectifier according to the present invention will be described in detail with reference to the accompanying drawings. Described exemplary embodiments are provided so that those skilled in the art may easily understand the technical spirit of the present invention, so that the present invention is not limited by the exemplary embodiments. Further, matters in the accompanying drawings are illustrated for easily describing the exemplary embodiments of the present invention, and may be different from actually implemented forms.

Further, an expression “including elements” is an open expression, and simply indicates that corresponding elements exist, and shall not be understood that additional elements are excluded.

Further, expressions, such as “first, second, . . . ” are expressions used only for the purpose of discriminating a plurality of elements, and does not limit an order between the elements or other characteristics.

Hereinafter, a rectifier according to an exemplary embodiment of the present invention will be described.

The rectifier according to the exemplary embodiment of the present invention may include a first semiconductor layer, a second semiconductor layer, and a third semiconductor layer which are sequentially disposed in a joined state.

Here, the first semiconductor layer and the third semiconductor layer may be formed of a semiconductor layer having the same type, and the second semiconductor layer may be formed of a semiconductor layer having a different type between the first semiconductor layer and the third semiconductor layer. Accordingly, 1) in a case where the first semiconductor layer and the third semiconductor layer are formed of a p-type semiconductor layer, the second semiconductor layer is formed of an n-type semiconductor layer to form a PNP semiconductor structure, and 2) in a case where the first semiconductor layer and the third semiconductor layer are formed of the n-type semiconductor layer, the second semiconductor layer is formed of the p-type semiconductor layer to form an NPN semiconductor structure.

Further, the second semiconductor layer may be formed in a spatially graded doped state between the first semiconductor layer and the third semiconductor layer. Particularly, the semiconductor layer may be formed in a form in which a doping concentration is changed while having a falling or rising inclination according to a change in a distance of the second semiconductor layer from the first semiconductor layer or the third semiconductor layer. The reason is that a high rectifying characteristic may be implemented through the graded doping of the second semiconductor layer.

In the meantime, the first semiconductor layer, the second semiconductor layer, and the third semiconductor layer may be formed by various methods, for example, an ion implant process and an epitaxial growth process.

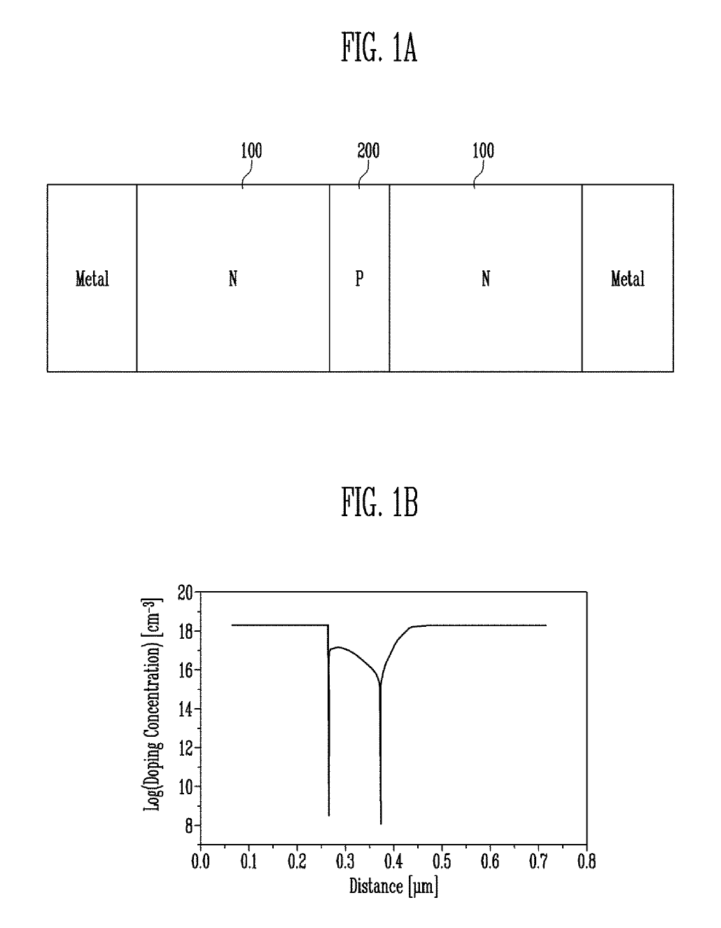

Hereinafter, a detailed example of the rectifier according to the exemplary embodiment of the present invention will be described with reference to FIGS. 1 to 4.

Hereinafter, the rectifier representatively formed in the NPN semiconductor structure will be described, but descriptions may be applied to the PNP semiconductor structure as a matter of course.

Referring to FIG. 1A, the rectifier according to the exemplary embodiment of the present invention may include a first semiconductor layer 100 formed in the n-type, a second semiconductor layer 200 formed in the P-type, and a third semiconductor layer 300 formed in the n-type. The first semiconductor layer 100, the second semiconductor layer 20, and the third semiconductor layer 300 may be sequentially joined to form the NPN semiconductor structure.

Further, the second semiconductor layer 200 may be formed in a spatially graded doped state between the first semiconductor layer 100 and the third semiconductor layer 300. Particularly, the second semiconductor layer 200 may be formed in a form in which a doping concentration (a concentration at which a group 13 element and the like is doped) of the second semiconductor layer 200 is changed while having a falling or rising inclination according to a change in a distance of the second semiconductor layer 200 from the first semiconductor layer 100 or the third semiconductor layer 300 as illustrated in the graph of FIG. 1B.

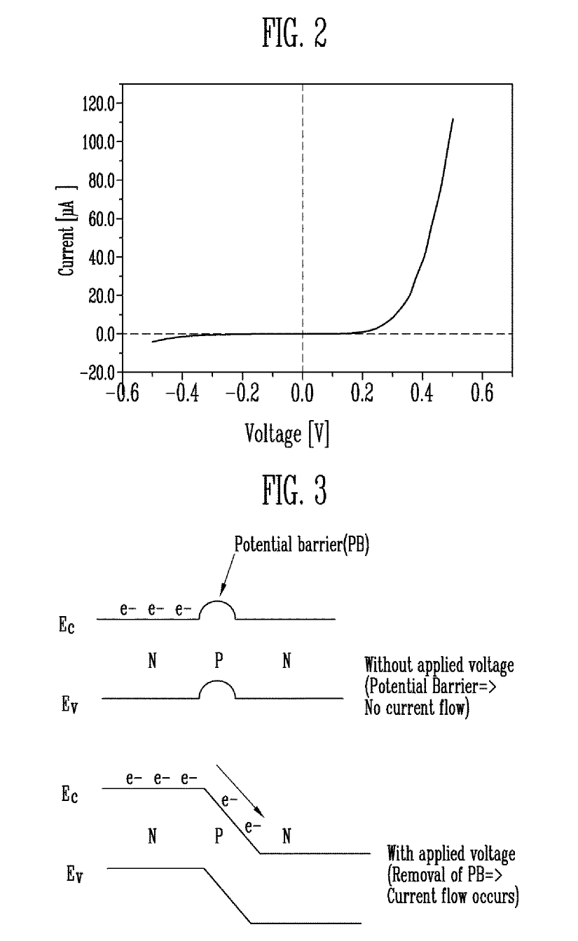

FIG. 2 illustrates an I-V characteristic of the rectifier which can be seen in FIGS. 1A and 1B. Referring to FIG. 2, it can be seen that a good rectifying characteristic is implemented by the spatial graded doping of the second semiconductor layer 200 (for reference, when the second semiconductor layer is not graded-doped, a symmetric I-V characteristic is implemented different from that of FIG. 2, so that a good rectifying characteristic may not be implemented).

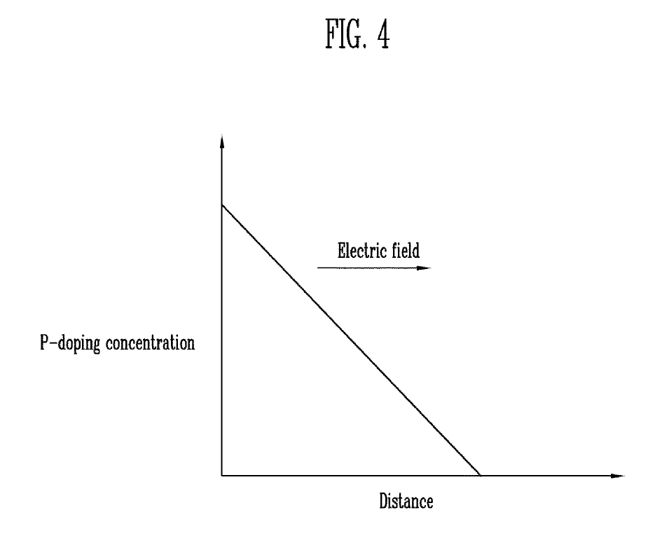

FIG. 3 illustrates a principle of flow of a current in the rectifier according to application of a voltage. As can be seen in FIG. 3, when a voltage is not applied or a voltage is low, electrons cannot pass a potential barrier, a current does not flow (an upper drawing in FIG. 3), but when a voltage of a predetermined level or higher is applied, electrons may easily pass a lowered potential barrier, so that a current flows (a lower drawing in FIG. 3).

FIG. 4 illustrates an internal electric field generated by the spatial graded doping of the second semiconductor layer 300. As can be seen in FIG. 4, an internal electric field is generated in a specific direction by the spatial graded doping of the second semiconductor layer 200. Accordingly, the electrons may pass well in one direction and may not pass well in the other direction, so that a rectifying action is incurred. Further, in this case, differently from a general PN diode (a current flows by diffusion of a carrier), a movement of charges by drift is caused, thereby implementing a rapid operation speed (Implement a high speed rectifying operation)

The aforementioned rectifier according to the exemplary embodiment of the present invention may implement a high speed rectifying characteristic, thereby being utilized in a technical field of detecting terahertz (THz) waves. Further, the rectifier according to the exemplary embodiment of the present invention may be utilized in various fields demanding a high speed rectifying characteristic, as well as the terahertz detecting field.

In the meantime, the rectifier according to the exemplary embodiment of the present invention may have various design variables, such as a doping concentration of the first semiconductor layer, a graded doping concentration of the second semiconductor layer, a doping concentration of the third semiconductor layer, and a width of the second semiconductor layer (a width between the first semiconductor layer and the third semiconductor layer), so that it is possible to freely adjust a high speed rectifying characteristic by freely adjusting the design variables. Particularly, the rectifier according to the exemplary embodiment of the present invention may have various design variables, so that it is possible to freely implement a characteristic without being limited to the trade-of relationship between specific performance. (For reference, the Schottky diode used for implementing the high speed rectifying operation in the related art substantially has only one design variable (a doping concentration of the semiconductor), so that there is a problem in that it is difficult to freely design the characteristic, and the characteristic implementation is limited to the trade-off relationship between a rectifying action and a response speed.)

For example, the rectifier according to the exemplary embodiment of the present invention may adjust capacitance for each unit area of the rectifier by adjusting the width of the semiconductor layer.

Further, the rectifier according to the exemplary embodiment of the present invention may adjust responsivity by adjusting the doping concentration of the first semiconductor layer or the semiconductor layer. The reason is that the responsivity is determined by a quantity of current transferred between the first semiconductor layer and the third semiconductor layer.

Further, the rectifier according to the exemplary embodiment of the present invention may adjust the rectifying characteristic by adjusting a graded doping concentration of the second semiconductor layer. The reason is that the internal electric field may be adjusted according to the graded doping concentration of the second semiconductor layer, and thus the rectifying characteristic may be adjusted.

Further, the rectifier according to the exemplary embodiment of the present invention may adjust various performance in addition to the aforementioned performance.

Hereinafter, a terahertz detector according to an exemplary embodiment of the present invention will be described.

The terahertz detector according to the exemplary embodiment of the present invention may include a plurality of first type semiconductors formed of semiconductors having the same type, and a second type semiconductor formed between the plurality of first type semiconductors, formed of a semiconductor having a different type from that of the plurality of first type semiconductors, and formed in a graded doped state.

Particularly, the terahertz detector according to the exemplary embodiment of the present invention may include 1) an NPN structure formed by an n-type semiconductor, a graded doped p-type semiconductor, and an n-type semiconductor which are sequentially joined, or 2) a PNP structure formed by a p-type semiconductor, a graded doped n-type semiconductor, and a p-type semiconductor which are sequentially joined.

The terahertz detector may detect the terahertz by converting a terahertz field applied in the NPN structure or the PNP structure formed by the plurality of first type semiconductors and the second type semiconductor into a current.

In the meantime, the plurality of first type semiconductors and the graded doped second type semiconductor may correspond to the aforementioned first semiconductor, graded doped second semiconductor, and third semiconductor. Accordingly, a detailed description will be omitted for preventing overlapping description, but the aforementioned characteristic related to the first semiconductor, the graded doped second semiconductor, and the third semiconductor may also be applied to the plurality of first type semiconductors and the graded doped second type semiconductor.

Hereinafter, a method of manufacturing a rectifier according to an exemplary embodiment of the present invention will be described.

The method of manufacturing a rectifier according to an exemplary embodiment of the present invention may include setting a parameter of semiconductor layer having the same type or setting a parameter of a semiconductor layer graded doped in a different from that of the semiconductor layers having the same type (step a), and forming a semiconductor structure in which the graded doped semiconductor layer is joined between the semiconductor layers having the same type (step b).

Step a is a step of setting the parameter of detailed semiconductors to form the rectifier. Particularly, step a is a step in which the parameter of the semiconductor layers having the same type forming the rectifier and a parameter of the semiconductor layer graded doped in a different type from that of the semiconductor layers having the same type are set. Here, the parameter of the semiconductor layers having the same type may be a doping concentration of each semiconductor layer, and the parameter of the graded doped semiconductor layer may be “a doping concentration of the graded doped semiconductor layer” or “a width of the graded doped semiconductor layer”.

Step b is a step of forming the semiconductor structure by joining the semiconductor layers having the same type and the graded-doped semiconductor of which the parameters are set. Particularly, step b is a step of forming the semiconductor structure by joining the graded doped semiconductor layer between the semiconductor layers having the same type.

In this case, 1) the semiconductor layers having the same type are formed of the p-type semiconductor layers, and the graded doped semiconductor layer is formed of the n-type semiconductor layer to form the PNP semiconductor structure, or 2) the semiconductor layers having the same type are formed of the n-type semiconductor layers, and the graded doped semiconductor layer is formed of the p-type semiconductor layer to form the NPN semiconductor structure.

Further, the semiconductor structure may be formed by an ion implant process or an epitaxial growth process.

In the meantime, the terahertz detector or the method of manufacturing the rectifier according to the exemplary embodiment of the present invention may include substantially the same technical characteristic as that of the rectifier according to the exemplary embodiment of the present invention even though a category thereof is different.

Accordingly, a detailed description will be omitted for preventing overlapping description, but the aforementioned characteristic related to the rectifier may also be applied to the terahertz detector or the method of manufacturing the rectifier according to the exemplary embodiment of the present invention as a matter of course.

As described above, the embodiment has been disclosed in the drawings and the specification. The specific terms used herein are for purposes of illustration, and do not limit the scope of the present invention defined in the claims. Accordingly, those skilled in the art will appreciate that various modifications and another equivalent example may be made without departing from the scope and spirit of the present disclosure. Therefore, the sole technical protection scope of the present invention will be defined by the technical spirit of the accompanying claims.

What is claimed is:

1. A rectifier, comprising:
a first semiconductor layer;
a second semiconductor layer; and
a third semiconductor layer,
wherein the first semiconductor layer and the third semiconductor layer are formed of semiconductor layers having the same type, and
the second semiconductor layer is formed between the first semiconductor layer and the third semiconductor layer, is formed of a semiconductor layer having a different type from that of the first semiconductor layer and the third semiconductor layer, and is formed in graded doped state.

2. The rectifier of claim 1, wherein the second semiconductor layer is formed in the spatially graded doped state between the first semiconductor layer and the third semiconductor layer.

3. The rectifier of claim 1, wherein the first semiconductor layer and the third semiconductor layer are formed of p-type semiconductor layers, and the second semiconductor layer is formed of a graded doped n-type semiconductor layer.

4. The rectifier of claim 1, wherein the first semiconductor layer and the third semiconductor layer are formed of n-type semiconductor layers, and the second semiconductor layer is formed of a graded doped p-type semiconductor layer.

5. The rectifier of claim 1, wherein the rectifier is operated as a terahertz detector based on a high speed rectifying operation.

6. The rectifier of claim 1, wherein the first semiconductor layer, the second semiconductor layer, or the third semiconductor layer is formed through an ion implant process or an epitaxial growth process.

7. A terahertz (THz) detector, comprising:
a plurality of first type semiconductors formed of semiconductors having the same type; and
a second type semiconductor formed between the plurality of first type semiconductors, formed in a different type from that of the plurality of first type semiconductors, and formed in a graded doped state.

8. The terahertz detector of claim 7, wherein the second type semiconductor is formed in the graded doped state according to a change in a distance from the first type semiconductor.

9. A method of manufacturing a rectifier, comprising:
setting a parameter of semiconductor layers having the same type, or a parameter of a semiconductor layer graded doped in a different type from that of the semiconductor layers having the same type; and
forming a semiconductor structure in which the graded doped semiconductor layer is joined between the semiconductor layers having the same type.

10. The method of claim 9, wherein the setting of the parameter of the semiconductor layers having the same type, or the parameter of the semiconductor layer graded doped in the different type from that of the semiconductor layers having the same type includes setting doping concentrations of the semiconductor layers having the same type, a width of the graded doped semiconductor layer, or a doping concentration of the graded doped semiconductor layer.
